(19) United States
(12) Patent Application Publication
(10) Pub. No.: US 2020/0006238 A1
(43) Pub. Date: Jan. 2, 2020

(54) SEMICONDUCTOR MODULE

(71) Applicant: Taiyo Yuden Co., Ltd., Tokyo (JP)

(72) Inventors: Hideki YOKOTA, Tokyo (JP); Yuichi SASAJIMA, Tokyo (JP)

(21) Appl. No.: 16/456,398

(22) Filed: Jun. 28, 2019

(30) Foreign Application Priority Data
Jun. 29, 2018 (JP) 2018-124019

(51) Int. Cl. H01L 23/538; H01L 23/31

(52) U.S. Cl. CPC H01L 23/5386; H01L 23/3121

(57) ABSTRACT

A semiconductor module includes: a dielectric film that has a first surface and a second surface opposed to the first surface, the first surface including a first mounting area and a second mounting area, the second surface including a first area and a second area, the first area facing the first mounting area, the second area facing the second mounting area; a plurality of circuit parts that includes a first circuit part and a second circuit part, the first circuit part being mounted on the first mounting area, the second circuit part being mounted on the second mounting area; a sealing layer that is provided on the first surface and covers the plurality of circuit parts; and an electrode layer that includes a first electrode group and a second electric group, the first electrode group including a plurality of first electrode terminals that covers substantially the entire area of the first area and is to be electrically connected to the first circuit part, the second electrode group including a plurality of second electrode terminals that covers substantially an entire area of the second area and is to be electrically connected to the second circuit part.

### CROSS-REFERENCE TO RELATED APPLICATION

This application claims the benefit of Japanese Application No. 2018-124019, filed Jun. 29, 2018, which is hereby incorporated by reference in its entirety.

### BACKGROUND

The present disclosure relates to a semiconductor module in which a circuit part and an electrode layer are respectively disposed on one surface of a dielectric layer and the other surface.

In recent years, a surface mount integrated power module called POL (Power Over Lay) has been known (see, for example, Japanese Patent Application Laid-open No. 2014-27272). A semiconductor module of this type typically includes a dielectric film such as polyimide, a circuit part such as a power semiconductor device and a passive part mounted on one surface of the dielectric film, an electrode layer disposed on the other surface of the dielectric film, a sealing layer that covers the circuit part, and the like.

In accordance with the semiconductor module, the circuit part is electrically connected to the electrode layer via the dielectric film, and thus, it is possible to realize a power semiconductor module that achieves high integration of parts and shortening of the wiring length and that can be thinner and miniaturized while securing an insulation withstand voltage. Further, the design freedom of the electrode shape is high, and it is possible to form the electrode terminal in the power semiconductor device that controls passage of a large current into an arbitrary shape and size, thereby improving heat dissipation.

### SUMMARY

In this type of a semiconductor module, since a support substrate that supports a circuit part includes a dielectric film, there is a problem that a warp of the dielectric film occurs due to the density of electrode terminals at the time of mounting on an external substrate (motherboard), which impairs the mounting reliability.

In view of the circumstances as described above, it is desirable to provide a semiconductor module capable of improving the mounting reliability by suppressing a warp of a dielectric film due to the density of electrode terminals.

In accordance with an embodiment of the present disclosure, there is provided a semiconductor module, including: a dielectric film; a plurality of circuit parts; a sealing layer; and an electrode layer.

The dielectric film has a first surface and a second surface opposed to the first surface. The first surface includes a first mounting area and a second mounting area. The second surface includes a first area and a second area, the first area facing the first mounting area, the second area facing the second mounting area.

The plurality of circuit parts includes a first circuit part and a second circuit part, the first circuit part being mounted on the first mounting area, the second circuit part being mounted on the second mounting area.

The sealing layer is provided on the first surface and covers the plurality of circuit parts. The electrode layer includes a first electrode group and a second electric group. The first electrode group includes a plurality of first electrode terminals that covers substantially the entire area of the first area and is to be electrically connected to the first circuit part. The second electrode group includes a plurality of second electrode terminals that covers substantially an entire area of the second area and is to be electrically connected to the second circuit part.

In the semiconductor module, since the first electrode group and the second electrode group are respectively disposed so as to cover substantially the entire area of the first area and the second area, the density of the electrode layer on the second surface is averaged. As a result, it is possible to improve the mounting reliability by suppressing a warp of the dielectric film due to the density of the electrode terminals.

The second electrode group may include a pair of comb-shape electrode terminals adjacent to each other via a gap, the second electrode group covering the entire area of the second area excluding the gap and margin area in a periphery of the second area.

The gap may have a size of not less than 10 μm and not more than 100 μm, and the margin area may have a width of not less than 50 μm and not more thanlμm.

The first electrode group may further include a plurality of dummy terminals arranged between the plurality of first electrode terminals.

The plurality of dummy terminals may include an annular portion disposed around the plurality of first electrode terminals.

The annular portion may include an extending portion that extends to the second area across a boundary between the first area and the second area.

The plurality of dummy terminals may include a metal layer filled in a hole provided in the dielectric film.

At least a part of the plurality of dummy terminals may include a plurality of openings.

The first area and the second area may be formed so that a ratio of occupied area thereof with respect to the second surface falls within a range of 1:1 to 2:1.

The second circuit part may include a power semiconductor device, and the first circuit part may include an IC part that controls the power semiconductor device.

The dielectric film may be formed of polyimide.

As described above, in accordance with the present disclosure, it is possible to improve the mounting reliability by suppressing a warp of the dielectric film due to the density of the electrode

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a schematic perspective view of a semiconductor module according to an embodiment of the present disclosure;

FIG. 2 is a schematic cross-sectional view of main portions of the semiconductor module;

FIG. 3 is a diagram showing an arrangement example of electrode terminals of the semiconductor module;

FIG. 4 is an equivalent circuit diagram of main portions of the semiconductor module;

FIG. 5 is a schematic bottom view showing a configuration of an electrode layer of the semiconductor module;

FIG. 6 is a diagram showing a modified example of the configuration shown in FIG. 5;

FIG. 7 is a schematic bottom view of a semiconductor module according to another embodiment of the present disclosure.

FIG. 8 is a schematic bottom view of a semiconductor module according to still another embodiment of the present disclosure.

### DETAILED DESCRIPTION OF EMBODIMENTS

Hereinafter, embodiments of the present disclosure will be described with reference to the drawings.

### First Embodiment

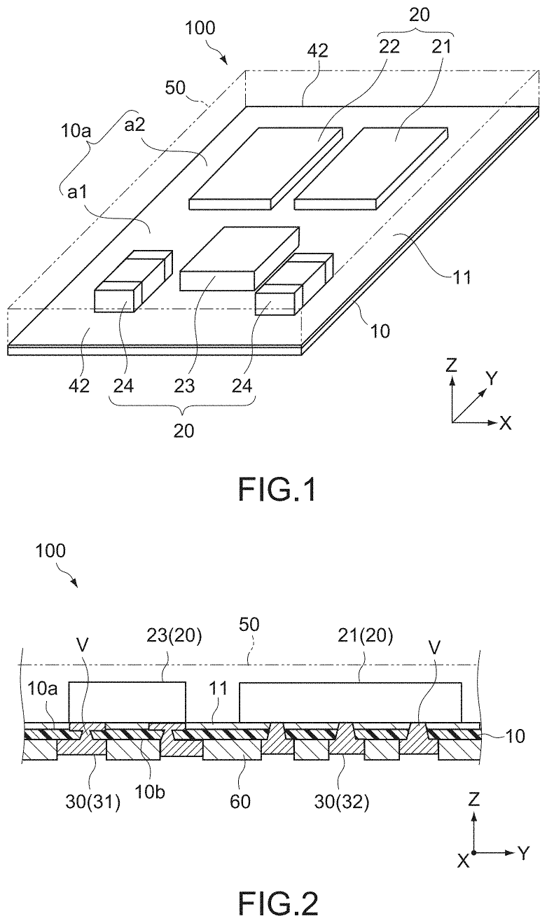

FIG. 1 is a schematic perspective view of a semiconductor module 100 according to an embodiment of the present disclosure. FIG. 2 is a schematic cross-sectional view of the semiconductor module 100. In each figure, the X axis, Y axis, and Z axis represent three axis directions orthogonal to each other, the X axis and Y axis correspond to the in-plane direction of the semiconductor module 100, and the Z axis corresponds to the thickness direction of the semiconductor module 100.

The semiconductor module 100 includes a dielectric film 10, a plurality of circuit parts 20, an electrode layer 30, and a sealing layer 50. Note that depending on the form of the module, it is not necessary need to provide the sealing layer 50.

[Dielectric Film]

The dielectric film 10 is formed of an electrically insulating resin material having a predetermined thickness. In this embodiment, the dielectric film 10 includes a polyimide film having a thickness of 25 Polyimide is very advantageous from the viewpoints of processability, insulation withstand voltage characteristics, chemical resistance, and the like.

The present disclosure is not limited thereto, and the dielectric film 10 has flexibility. The thickness of the dielectric film 10 can be appropriately set in accordance with the dielectric constant of the material, the magnitude of the insulation withstand voltage, or the like. For example, the thickness of the dielectric film 10 is appropriately selected within the range of not more than 20 μm and not less than 50 The dielectric material is also not limited to polyimide. For example, an appropriate material such as polytetrafluoroethylene (PTFE), polysulfone, and a liquid crystal polymer can be adopted.

The shape of the dielectric film 10 is also not particularly limited, and the dielectric film 10 is typically formed in a rectangular shape. The size of the dielectric film 10 is also not particularly limited. In this embodiment, the dielectric film 10 has a long side parallel to the Y-axis direction of not less than 10 mm and not more than 20 mm and a short side parallel to the X-axis direction of not less than 5 mm and not more than 15 mm.

The dielectric film 10 has a first surface 10a and a second surface 10b opposed to the first surface 10a (see FIG. 2). The first surface 10a is a mount surface on which the plurality of circuit parts 20 are to be mounted, and has a first mount area a1 and a second mount area a2. On the first and second mount areas a1 and a2, the plurality of circuit parts 20 is to be mounted via an adhesive layer 11. The electrode layer 30 to be electrically connected to the plurality of circuit parts 20 is disposed on the second surface 10b via the dielectric film 10.

The relationship between the positions and sizes of the first mount area a1 and the second mount area a2 is not particularly limited. In this embodiment, the first and second mount areas a1 and a2 correspond to respective areas obtained by dividing the dielectric film 10 in the long side direction (Y-axis direction), and have the same or substantially the same size in this example.

The adhesive layer 11 includes a liquid adhesive or a film-like adhesive sheet applied to the first surface 10a. The type of the adhesive layer 11 is not particularly limited. The adhesive layer 11 is formed of an appropriate insulating resin material such as an epoxy resin material and an acrylic resin material. The thickness of the adhesive layer 11 is not particularly limited, and is, for example, 15 μm. Note that the adhesive layer 11 is formed on the entire area of the dielectric film 10 in this example. The adhesive layer 11 may be partially formed on the dielectric film 10, or may be partially formed below the circuit part 20, for example.

[Circuit Part]

The plurality of circuit parts 20 are mounted on the adhesive layer 11 on the first surface 10a of the dielectric film 10. The plurality of circuit parts 20 typically includes active parts such as semiconductor devices. As the semiconductor devices, an IC part and a discrete part are used. In this embodiment, the semiconductor devices include a power transistor 21 and a diode 22 through which a large current flows. The semiconductor devices further include a control IC 23 that controls the power transistor 21. The circuit parts 20 further include passive parts 24 such as a capacitor and a resistor. A predetermined circuit part among the circuit parts 20 is electrically connected to the electrode layer 30. Note that the circuit parts 20 (21 and 22) are not limited to the combination of the power transistor 21 and the diode 22, and may be two power transistors connected in series like an inverter circuit.

The power transistor 21 includes a BiP transistor, MOSFET, IGBT, or the like formed of Si, or a transistor formed of SiC, GaN, or the like. These semiconductor devices are mounted with the active surface facing the first surface 10a. A heat sink for heat radiation may be bonded to the inactive surface (corresponding to the back surface of the chip at the top of the figure) of each of the power transistor 21 and the power diode 22 via a bonding material such as solder and an Ag paste.

Among the plurality of circuit parts 20, the control IC 23 and the passive parts 24, which are first parts, are mounted on the first mount area a1 of the dielectric film 10, and power semiconductor devices such as the power transistor 21 and the power diode 22, which are second parts, are mounted on the second mount area a2 of the dielectric film 10.

[Sealing Layer]

The sealing layer 50 is provided on the first surface 10a of the dielectric film 10 so as to cover the plurality of circuit parts 20. The sealing layer 50 has a function of improving the rigidity of the dielectric film 10 and inhibiting the outside air containing moisture and the like from coming into contact with the circuit part 20. The sealing layer 50 is formed of a general-purpose electric insulating sealing material, typically, an epoxy synthetic resin material. Note that as described above, the sealing layer 50 may be omitted.

[Electrode Layer]

The electrode layer 30 is disposed on the second surface 10b of the dielectric film 10, and typically includes a metal plating layer formed on the second surface 10b. As the metal plating layer, typically, a cupper plating layer is adopted. The electrode layer 30 includes a via V (see FIG. 2) as an interlayer connection portion to be electrically connected to each of the circuit parts 20 via the dielectric film 10.

When forming the electrode layer 30, first, laser light is applied from the side of the second surface 10b to the electrode terminal of each of the circuit parts 20 mounted on the first surface 10a of the dielectric film 10. As a result, the dielectric film 10 and the adhesive layer 11 are drilled, and each electrode terminal is exposed to the side of the second surface 10b. Subsequently, a conductor layer to be a seed layer is formed on the second surface 10b by a sputtering method, and then, a cupper plating layer having a predetermined thickness is formed by an electrolytic plating method. As a result, the electrode layer 30 including the via V is formed.

For the formation of the conductor layer to be a seed layer, the sputtering method does not necessarily need to be adopted, and an electroless plating method may be adopted. The thickness (thickness from the second surface 10b) of the electrode layer 30 is not particularly limited, and is, for example, not less than approximately 20 μm and not more than 100 μm. As a result, the current characteristics of the electrode layer 30 and productivity can be secured.

Since the thickness of the dielectric film 10 is 25 μm as described above, an electrode having a thickness in a range of approximately the same as the thickness of the film to approximately twice the thickness of the film is obtained. The thickness relationship is completely different from that in the print board such as an epoxy board. In the second mount area a2, a polyimide sheet is used because a power switching device is handled. Although a large current flows through the power switching device and it generates high heat generation, driving and heat radiation are made possible by increasing the thickness of the electrode layer 30.

The electrode layer 30 is patterned into a plurality of electrode portions having a predetermined shape by using a photolithographic technology. Alternatively, the electrode layer 30 may include a plating film having a predetermined pattern shape via a plating resist (semi-additive method). As a result, it is possible to form an electrode pattern with high dimensional accuracy.

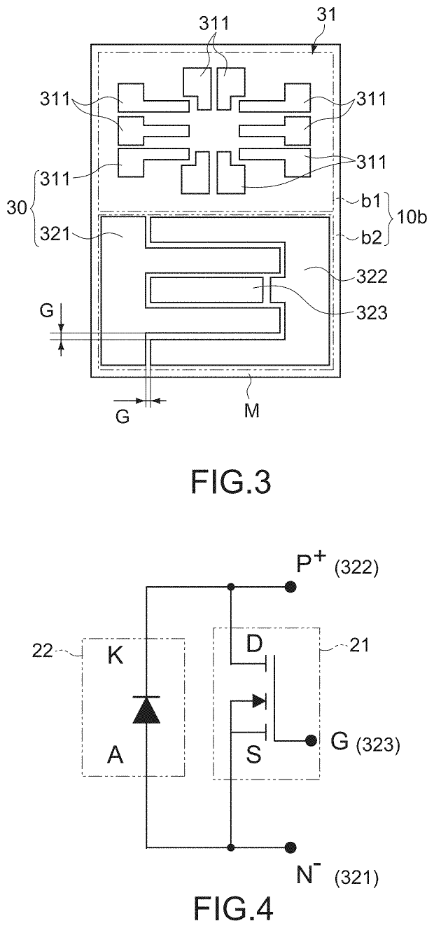

FIG. 3 is a bottom view (diagram showing the back surface of the dielectric film 10) of the semiconductor module 100 showing an example of the conductive pattern such as an electrode terminal and a wiring constituting the electrode layer 30. As shown in the figure, the electrode layer 30 includes a plurality of first electrode terminals 311 arranged in a first area b1 and a plurality of second electrode terminals 321, 322, and 323 arranged in a second area b2.

The first area b1 is an area on the side of the second surface 10b, which faces the first mount area a1 of the dielectric film 10. The plurality of first electrode terminals 311 are electrically connected to the circuit parts 20 (the control IC 23 and the passive parts 24) mounted on the first mount area a1. Note that in FIG. 3, a pattern diagram of a rewiring connected to the control IC 23 and the electrode connected to the rewiring is shown.

The second area b2 is an area on the side of the second surface 10b, which faces the second mount area a2 of the dielectric film 10. The second electrode terminals 321 to 323 are electrically connected to the circuit parts 20 (the power transistor 21 and the diode 22) mounted on the second mount area a2. Of the plurality of second electrode terminals 321 to 323, the electrode terminals 321 and 322 include a pair of comb-shaped electrode terminals adjacent in the X-axis direction via a predetermined gap G, and the electrode terminal 323 is formed in a straight shape that is long in the X-axis direction and disposed between the electrode terminals 321 and 322. Note that the shape and presence or absence of the terminal (electrode) of the electrode terminal 323 are determined by, for example, the connection structure formed in the second area b2 shown in FIG. 4.

The first electrode terminal 321 is connected to a source terminal (S) of the power transistor 21 and an anode terminal (A) of the power diode 22. The second electrode terminal 322 is connected to a drain terminal (D) of the power transistor 21 and a cathode terminal (K) of and the power diode 22. The third electrode terminal 323 is connected to a gate terminal (G) of the power transistor 21. FIG. 4 is an equivalent circuit diagram of main portions of the semiconductor module 100.

Note that the circuit shown in FIG. 4 is an example. As another example, also a circuit in which two power transistors are connected in series, which is adopted in an inverter circuit, is conceivable. In this case, reference symbols 21 and 22 each indicate a power transistor. In any case, the second mounting area on which this transistor is mounted is a portion where a large current flows and high heat is generated.

The semiconductor module 100 further includes a solder resist layer 60 (see FIG. 2). The solder resist layer 60 is provided on the second surface 10b of the dielectric film 10, and opens a predetermine area of the electrode layer 30. The solder resist layer 60 may include a plating resist layer used in forming the electrode layer 30. Note that the film thickness of the solder resist layer 60 is 60 μm to 80 μm.

The dimensions of the respective portions will be organized. Note that the following values are merely examples, and the present disclosure is not limited thereto.

| | |
|---|---|
| Thickness of dielectric film 10 | 20 μm to 50 μm |
| Thickness of electrode layer 30 | 50 μm to 100 μm |
| Width of common electrode | 1.2 mm |
| connecting comb teeth | |
| Width of comb teeth | 0.8 mm |
| Width of another conductive | approximately 0.3 mm (300 μm) |
| pattern | |
| Thickness of sealing layer 50 | 1 mm to 2 mm (1000 μm to 2000 μm) |
| Thickness of solder resist layer | 60 μm to 80 μm |

Note that as shown in FIG. 3, the plurality of first electrode terminals 311 are sparsely arranged at predetermined positions on the first area b1. Meanwhile, a current, which is larger than the current that flows through the first electrode terminals 311, flows through the plurality of second electrode terminals 321 to 323 and it is necessary to secure a heat radiation area for the plurality of second electrode terminals 321 to 323. Therefore, the plurality of second electrode terminals 321 to 323 are each formed to have a width larger than that of each of the first electrode terminals 311, and are densely arranged so as to cover substantially the entire area (the entire area of the second area b2 excluding the gap G between the pair of comb-shape electrode terminals and a margin area M in the periphery of the second area b2) of the second area b2. As a result, since the electrode layer 30 is sparsely/densely distributed in the first area b1 and the second area b2, there is a possibility that a warp of the dielectric film 10 occurs at the time of mounting on the external substrate (motherboard), which impairs the mounting reliability. A warp occurs due to the thinness of the dielectric film 10 in the area in which the electrode terminal 311 is not provided in the first area b1, particularly an area close to the corner portion. In the first area b1 in which electrode terminals are sparsely arranged and the second area b2 in which electrode terminals are densely arranged, a warp easily occurs particularly with the vicinity of the boundary of these areas as a base line.

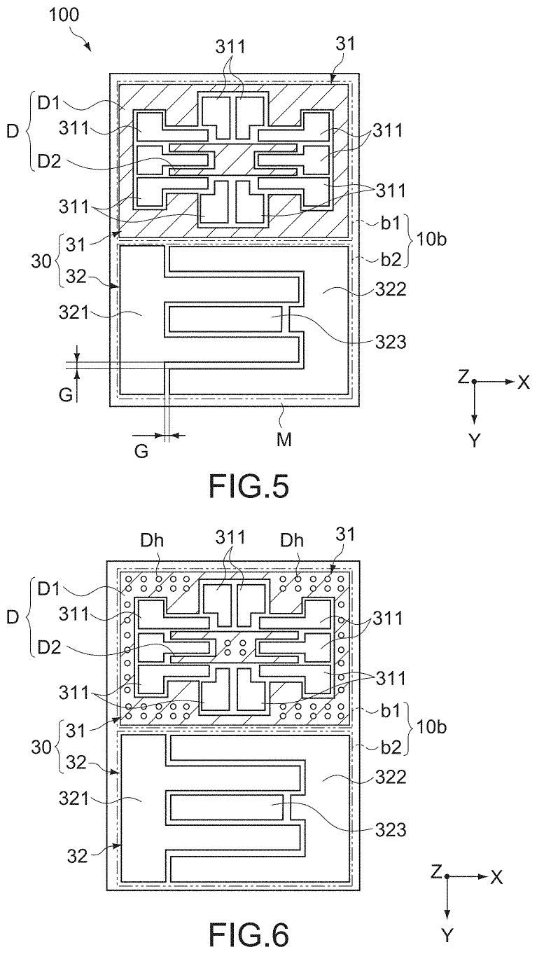

In order to solve this, in the semiconductor module 100 according to this embodiment, as shown in FIG. 5, a dummy electrode D (indicated by a hatched area in the figure, the same applies hereinafter) is disposed in the area in which the first electrode terminal 311 is not formed in the first area b1. The dummy electrode D is not connected to any of the first electrode terminals 311, the second electrode terminals 321 to 323, and the circuit parts 20 on the first mount area a1, and is disposed on the first area b1 to be isolated. Alternatively, the dummy electrode D may be grounded to GND. In this case, the dummy electrode D may be provided separately from the GND terminal provided in the control IC 23. Alternatively, as will be described below, the dummy electrode D may be integrally connected to another electrode terminal constituting the electrode layer 30.

The dummy electrode D and the plurality of first electrode terminals 311 constitute a first electrode group 31 disposed on the first area b1. The first electrode group 31 is disposed so as to cover almost the entire area of the first area b1. Meanwhile, the second electrode terminals 321 to 323 constitute a second electrode group 32 disposed on the second area b2. The second electrode group 32 is disposed so as to cover substantially the entire area (the entire area of the second area b2 excluding the gap G between the pair of comb-shape electrode terminals and the margin area M in the periphery of the second area b2) of the second area b2. The size of the gap G is, for example, not less than 10 μm and not more than 100 μm, and the width of the margin are M is, for example, not less than 50 μm and not more than 100 μm. The first area b1 and the second area b2 is formed so that the ratio of the occupied areas with respect to the second surface 10b is, for example, 1:1 to 2:1.

As a result, the electrode layer 30 is formed in the first area b1 and the second area b2 without sparse/dense distribution. Therefore, it is possible to suppress a warp of the dielectric film 10 at the time of mounting on the external substrate (motherboard). Further, since the dummy electrode D is provided also in the area in the vicinity of the corner portion of the first area b1, it is also possible to suppress a warp of this area.

In this embodiment, the dummy electrode D includes an annular portion D1 disposed around the plurality of first electrode terminals 311 and a band-shape portion D2 disposed between the plurality of first electrode terminals 311. The annular portion D1 is formed in a rectangular annular shape along the periphery of the first area b1. The band-shape portion D2 includes a comb-tooth portions alternately arranged on predetermined electrode terminals among the plurality of first electrode terminals 311. As a result, it is possible to increase the occupied area of the first electrode group 31 with respect to the first area b1.

The dummy electrode D does not necessarily need to include two blocks, i.e., the annular portion D1 and the band-shape portion D2, and may include one block or three or more blocks. Also the shape of each of the blocks constituting the dummy electrode D is not limited to the above-mentioned example, and an arbitrary shape may be set depending on the arrangement form or the like of the second electrode group 32 on the second area b2.

Typically, the shape and position of the dummy electrode D are designed so that the density of electrodes of the electrode layer 30 can be averaged on the second surface 10b. For example, the first electrode group 31 and the second electrode group 32 are formed so that the occupied areas of the electrodes with respect to the second surface 10b are equal to each other.

The shape and position of the dummy electrode D is not limited, and an appropriate number of thinning openings Dh having an appropriate shape may be provided at appropriate positions in the plane as shown in FIG. 6. Also in such a method, it is possible to adjust the electrode area. Further, since the surface area contributing the heat radiation of the dummy electrode increases due to the formation of the openings Dh, it can be used to adjust the amount of heat radiation. Such a configuration can be applied similarly to the second electrode terminals 321 to 323 constituting the second electrode group 32.

Note that the circles of the openings Dh shown in the figure may be holes provided in the dielectric film 10. The electrode layer 30 is treated by plating as described above. Therefore, if the holes are provided in the dielectric film 10 before plating, the same metal layer as the electrode layer 30 is formed also in the hole portions by plating treatment. Therefore, the electrode layer 30 has such a structure that a rivet obtained by filling a hole with metal is stuck in a film, which increase the peeling strength. As a result, the rigidity of the entire film increases.

Further, an electrode material may be embedded in the holes integrally with the electrode layer 30, or an electrode pattern having a function similar to that of the dummy electrode D may be provided also on the side of the first surface 10a and a via hole metal, which is provided integrally with both the electrodes, may be provided so as to connect them.

The dummy electrode D is formed simultaneously with the first electrode terminals 311 and the second electrode terminals 321 to 323. The dummy electrode D is typically formed to have the same thickness as those of the first and second electrode terminals 311 and 321 to 323. As a result, the electrode layer 30 can be formed without performing a separate process for forming the dummy electrode D. After forming the electrode layer 30, the dummy electrode D is typically covered by the solder resist layer 60.

As described above, in the semiconductor module 100 according to this embodiment, since the first electrode group 31 and the second electrode group 32 are respectively arranged so as to cover the entire area of the first area b1 and the second area b2, the density of the electrode layer 30 on the second surface 10b is averaged. As a result, it is possible to improve the mounting reliability of the semiconductor module 100 by suppressing a warp of the dielectric film 10 due to the density of the electrode terminals 311 and 321 to 323.

### Second Embodiment

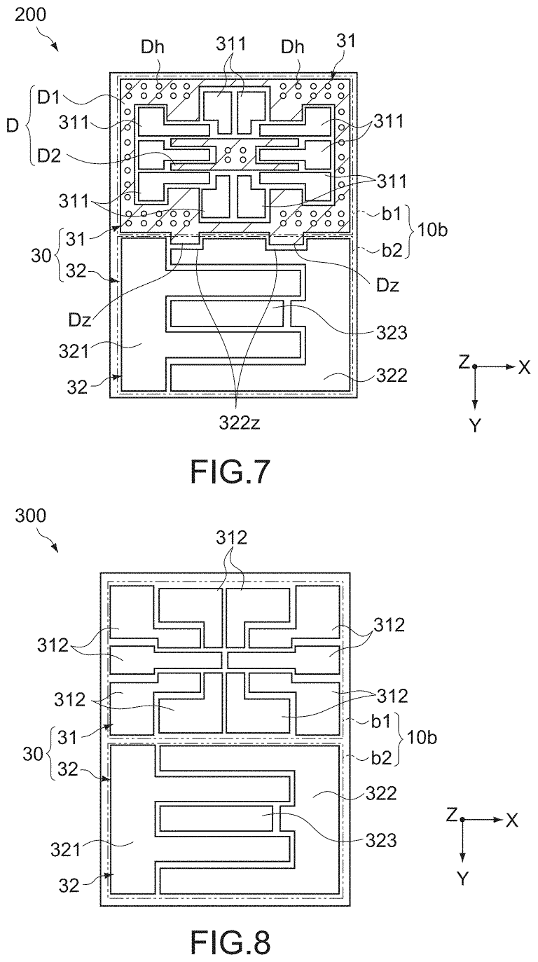

FIG. 7 is a bottom view of a semiconductor module 200 according to a second embodiment of the present disclosure on the side of the electrode layer. Hereinafter, the configuration different from that in the first embodiment will be mainly described, and the same configuration as that of the first embodiment will be denoted by the same reference symbol, and description thereof will be omitted or simplified.

In the semiconductor module 200 according to this embodiment, the annular portion D1 as the dummy electrode D includes extending portion Dz that extend to the second area b2 across the boundary between the first area b1 and the second area b2 on the second surface 10b. As a result, it is possible to inhibit the dielectric film 10 from bending starting from the boundary between the first area b1 and the second area b2.

The extending length of the extending portion Dz is not particularly limited as long as it can inhibit the dielectric film 10 from bending starting from the boundary between the first area b1 and the second area b2. In this case, as shown in FIG. 7, recesses 322z for avoiding interference with the extending portion Dz may be provided on the areas facing the second electrode terminals 322.

Note that by providing the openings Dh in the extending portion Dz or providing holes in the dielectric film 10 and embedding an electrode material in the holes integrally with the electrode layer 30, the peeling strength from the dielectric film 10 is enhanced. Further, an electrode pattern having a function similar to that of the dummy electrode D may be provided also on the side of the first surface 10a and a via hole metal, which is provided integrally with both the electrodes, may be provided so as to connect them.

In accordance with this embodiment, between the boundary of the first area b1 and the second area b2, the electrode layers thereof alternately enter, and thus, it is possible to suppress a warp at the boundary. Further, in the case where holes are provided in the dielectric film 10 and a metal is embedded therein integrally with the electrode layer as described above, the degree of adhesion increases and occurrence of the warp can be further suppressed by the thickness of the electrode.

### Third Embodiment

FIG. 8 is a bottom view of a semiconductor module 300 according to a third embodiment of the present disclosure on the side of the electrode layer. Hereinafter, the configuration different from that in the first embodiment will be mainly described, and the same configuration as that of the first embodiment will be denoted by the same reference symbol, and description thereof will be omitted or simplified.

The semiconductor module 300 according to this embodiment is different from the semiconductor module 100 according to the first embodiment in that the first electrode group 31 disposed in the first area b1 includes no dummy electrode and includes a plurality of first electrode terminals 312. Each of the first electrode terminals 312 has an area larger than that of each of the first electrode terminals 311 in the first embodiment, and the plurality of first electrode terminals 312 covers substantially the entire area of the first area b1. Also in this embodiment, the operation and effect similar to those in the first embodiment can be achieved.

Note that in FIG. 8, the extending portions Dz may be provided as in FIG. 7. Further, favorably, holes, which are provided in the film 10, may be provided in the extending portions, and a metal may be provided integrally with the electrode layer 30.

In the electrode terminals 312, 321, 322, and the like, the hole that does not overlap with the electrodes of the circuit parts does not penetrate the adhesive layer and is formed only in the film. The adhesive layer serves as a protective layer for the hole at the time of plating, which inhibits plating from leaking to the side of the first surface 10a. This applies also to the dummy electrode D in FIG. 6.

Further, by providing a hole in the film and covering the electrode layer by plating while filling the hole with the plating, the hole can be easily filled.

Now, the above-mentioned first to third embodiments (FIG. 5 to FIG. 8) will be organized in three points.

First, since the electrode layer having a thickness in the range of two times the thickness of the dielectric film to five times the thickness of the dielectric film, which includes the dummy pattern, is provided on the entire film, the rigidity and flatness of the electrode become dominant, and a warp in the semiconductor module is reduced. Further, by providing the dummy pattern also on the front side (side of the first surface) to sandwich the film, a warp is further suppressed.

Second, the slits (gaps) between the electrodes or wirings will be described. The space between the slits is set in accordance with the voltage between patterns and the processing accuracy. Therefore, it does not mean that any space can be set. That is, in FIG. 5, the space between the dummy pattern (D) and the conductive pattern (311) is a generally necessary space set in accordance with, for example, the withstand voltage characteristics or processing accuracy, and is not widened to be substantially larger than that. In general, it is approximately 10 μm to 100 μm.

Further, the space (margin area M) in the periphery of the dielectric film 10, particularly, in the periphery of the annular portion D1 of the dummy pattern and the film is generally approximately 50 to 100 μm also in consideration of the dicing accuracy. A space having a size of approximately the thickness of the electrode layer is opened.

Third, the ratio of the first electrode group and the second electrode group to the surface of the dielectric film will be described. First, the ratio of the first area b1 and the second area b2 varies in accordance with the power size of the transistor, and is generally 1:1 to 2:1. With respect to the ratio, the first electrode group 31 and the second electrode group 32 are provided on the entire area of the second area b2 excluding the slit (gap G) and (margin are M).

Although embodiments of the present disclosure have been described above, the present disclosure is not limited to the above-mentioned embodiments and various modifications can be made without departing from the essence of the present technology.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor module, comprising:
a dielectric film that has a first surface and a second surface opposed to the first surface, the first surface including a first mounting area and a second mounting area, the second surface including a first area and a second area, the first area facing the first mounting area, the second area facing the second mounting area;
a plurality of circuit parts that includes a first circuit part and a second circuit part, the first circuit part being mounted on the first mounting area, the second circuit part being mounted on the second mounting area;
a sealing layer that is provided on the first surface and covers the plurality of circuit parts; and
an electrode layer that includes a first electrode group and a second electric group, the first electrode group including a plurality of first electrode terminals that covers substantially the entire area of the first area and is to be electrically connected to the first circuit part, the second electrode group including a plurality of second electrode terminals that covers substantially an entire area of the second area and is to be electrically connected to the second circuit part.

2. The semiconductor module according to claim 1, wherein
the second electrode group includes a pair of comb-shape electrode terminals adjacent to each other via a gap, the second electrode group covering the entire area of the second area excluding the gap and margin area in a periphery of the second area.

3. The semiconductor module according to claim 2, wherein
the gap has a size of not less than 10 μm and not more than 100 μm, and
the margin area has a width of not less than 50 μm and not more thanl μm.

4. The semiconductor module according to claim 1, wherein
the first electrode group further includes a plurality of dummy terminals arranged between the plurality of first electrode terminals.

5. The semiconductor module according to claim 4, wherein
the plurality of dummy terminals includes an annular portion disposed around the plurality of first electrode terminals.

6. The semiconductor module according to claim 5, wherein
the annular portion includes an extending portion that extends to the second area across a boundary between the first area and the second area.

7. The semiconductor module according to claim 4, wherein
the plurality of dummy terminals includes a metal layer filled in a hole provided in the dielectric film.

8. The semiconductor module according to claim 1, wherein
at least a part of the plurality of dummy terminals includes a plurality of openings.

9. The semiconductor module according to claim 1, wherein
the first area and the second area are formed so that a ratio of occupied area thereof with respect to the second surface falls within a range of 1:1 to 2:1.

10. The semiconductor module according to claim 1, wherein
the second circuit part includes a power semiconductor device, and
the first circuit part includes an IC part that controls the power semiconductor device.

11. The semiconductor module according to claim 1, wherein
the dielectric film is formed of polyimide.
